(19) United States
(12) Patent Application Publication
(10) Pub. No.: US 2026/0096199 A1
(43) Pub. Date: Apr. 2, 2026

(54) STACKED FET WITH FLEXIBLE INTER-EPI DIELECTRIC THICKNESS

(71) Applicant: International Business Machines Corporation, Armonk, NY (US)

(72) Inventors: Debarghya Sarkar, Latham, NY (US); Ruilong Xie, Niskayuna, NY (US); Shay Reboh, Guilderland, NY (US); Junli Wang, Slingerlands, NY (US); Jay William Strane, Wappingers Falls, NY (US)

(21) Appl. No.: 18/899,564

(22) Filed: Sep. 27, 2024

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 64/017; H10D 64/018; H10D 84/0167; H10D 84/017; H10D 84/0188; H10D 84/038; H10D 88/01

(57) ABSTRACT

A semiconductor device including a second nanosheet transistor stacked over a first nanosheet transistor is provided which accommodates for having source/drain separating dielectric layers and/or stacked source/drain regions having a wide variety of vertical heights. The wide variety of heights can be along the same source/drain canyon or across different source/drain canyons.

### BACKGROUND

The present application relates to semiconductor technology, and more particularly to a semiconductor device, i.e., stacked field effect transistor (FET), that can accommodate for source/drain separating dielectric layers (i.e., inter-epi dielectric) and/or stacked source/drain regions having a wide variety of vertical heights.

A stacked FET is a configuration in which two FETs are vertically integrated on a semiconductor substrate. These FETs are stacked vertically on top of each other resulting in a compact structure that combines the individual benefits of each of the FETs. Stacked FETs have a reduced footprint and an increased efficiency compared to non-stacked FETs. The increased efficiency can include, for example, a lower on-state resistance, a lower gate charge and/or a parasitic inductance resistance.

### SUMMARY

A semiconductor device including a second nanosheet transistor stacked over a first nanosheet transistor is provided which accommodates for having source/drain separating dielectric layers and/or stacked source/drain regions having a wide variety of vertical heights. The wide variety of heights can be along the same source/drain canyon or across different source/drain canyons.

In one embodiment of the present application, the semiconductor device includes a first nanosheet transistor including a plurality of vertically stacked and spaced apart first device semiconductor channel material nanosheets, each first device semiconductor channel material nanosheet having a middle portion located in an active gate region and end portions located under a gate spacer, in which the middle portion of each first device semiconductor channel material nanosheet is thinner than the end portions of each first device semiconductor channel material nanosheet, a gate structure wrapping around the middle portion of each of the first device semiconductor channel material nanosheets, and a first device semiconductor material structure vertically aligned above each end portion of the first device semiconductor channel material nanosheets and having an inner sidewall in contact with the gate structure. The semiconductor device further includes a second nanosheet transistor stacked vertically above the first nanosheet transistor and including a plurality of vertically stacked and spaced apart second device semiconductor channel material nanosheets, each second device semiconductor channel material nanosheet having a middle portion located in the active gate region and end portions located under the gate spacer, wherein the middle portion of each second device semiconductor channel material nanosheet is thinner than the end portions of each second device semiconductor channel material nanosheet, the gate structure wrapping around the middle portion of each of the second device semiconductor channel material nanosheets, and a second device semiconductor material structure vertically aligned beneath each end portion of the second device semiconductor channel material nanosheets and having an inner sidewall in contact with the gate structure.

The semiconductor device mentioned above further includes a source/drain canyon located on each side of the first nanosheet transistor and the second nanosheet transistor. Each source/drain canyon includes a first device source/drain region and a second device source/drain region which are separated by a source/drain separating dielectric layer (i.e., an inter-epi dielectric).

### BRIEF DESCRIPTION OF THE DRAWINGS

FIG. 1 is a top down view of a device layout that can be used in the present application.

FIG. 2 is a cross sectional view through X1-X1 illustrated in FIG. 1 of a semiconductor device in accordance with an embodiment of the present application.

FIG. 3 is a cross sectional view through X1-X1 illustrated in FIG. 1 of another semiconductor device in accordance with an embodiment of the present application.

FIG. 4 is a cross sectional view through X1-X1 illustrated in FIG. 1 of yet another semiconductor device in accordance with an embodiment of the present application.

FIG. 5 is a cross sectional view through X1-X1 illustrated in FIG. 1 of a further semiconductor device in accordance with an embodiment of the present application.

FIG. 6A is a cross sectional view through X1-X1 illustrated in FIG. 1 of an exemplary structure that can be used in forming a semiconductor device in accordance with the present application, the exemplary structure including a semiconductor substrate, a first sacrificial semiconductor layer, a first device material stack of alternating first device sacrificial semiconductor material layers and first device semiconductor channel material layers, a second sacrificial semiconductor layer, a second device material stack of alternating second device sacrificial semiconductor material layers and second device semiconductor channel material layers.

FIG. 6B is a cross sectional view of the exemplary structure of FIG. 6A after forming a sacrificial gate structure and a gate spacer.

FIG. 6C is a cross sectional view of the exemplary structure of FIG. 6B after patterning the second device material stack, the second sacrificial semiconductor layer, the first device material stack and the first sacrificial semiconductor layer utilizing the sacrificial gate structure and the gate spacer as a combined etch mask.

FIG. 6D is a cross sectional view of the exemplary structure of FIG. 6C after forming first device inner spacers, second device inner spacers, a bottom dielectric isolation layer and a middle dielectric isolation layer.

FIG. 6E is a cross sectional view of the exemplary structure of FIG. 6D after forming a sacrificial placeholder material layer in a source/drain canyon.

FIG. 6F is a cross sectional view of the exemplary structure of FIG. 6E after forming a blocking spacer in the source/drain canyon and on top of the sacrificial placeholder material layer.

FIG. 6G is a cross sectional view of the exemplary structure of FIG. 6F after removing the sacrificial placeholder material layer.

FIG. 6H is a cross sectional view of the exemplary structure of FIG. 6G after forming a first device source/drain region at a bottom portion of the source/drain canyon.

FIG. 6I is a cross sectional view of the exemplary structure of FIG. 6H after forming a first device dielectric liner in the source/drain canyon and on top of the first device source/drain region.

FIG. 6J is a cross sectional view of the exemplary structure of FIG. 6I after forming a source/drain separating dielectric layer in the source/drain canyon and on top of the first dielectric liner.

FIG. 6K is a cross sectional view of the exemplary structure of FIG. 6J after recessing the blocking spacer and the first device dielectric liner.

FIG. 6L is a cross sectional view of the exemplary structure of FIG. 6K after forming a second device source/drain region on top of the source/drain separating dielectric layer

FIG. 6M is a cross sectional view of the exemplary structure of FIG. 6L after forming a second device dielectric liner in the source/drain canyon and on top of the second device source/drain region.

FIG. 6N is a cross sectional view of the exemplary structure of FIG. 6M after forming an interlayer dielectric (ILD) layer on the second device dielectric liner.

FIG. 6O is a cross sectional view of the exemplary structure of FIG. 6N after removing the sacrificial gate structure and releasing each second device semiconductor channel material nanosheet and each first device semiconductor channel material nanosheet.

FIG. 6P is a cross sectional view of the exemplary structure of FIG. 6O after performing a semiconductor channel material nanosheet thinning process.

FIG. 6Q is a cross sectional view of the exemplary structure of FIG. 6P after forming a gate structure and a gate cap.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. A stacked transistor (i.e., FET) includes one transistor stacked on top of another transistor. In the embodiment described in the present application, the stacked transistor includes stacked nanosheet transistors. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology.

Scaled stacked FETs face the problem of having non-uniformity of materials grown or deposited in high aspect ratio source/drain canyons. This a fundamental problem that arises owing to the difficulty of precursor traversal in high aspect ratio structures. For example, epitaxially grown source/drain regions have a wide variability of vertical heights and surface topography along the same source/drain canyon and/or across different source/drain canyons. In another example, the inter-epitaxial dielectric layer also has a wide variability of vertical heights owing to differences in recess depth that may occur. There is a need to obtain a semiconductor device including a stacked FET which will be able to accommodate these height variations without negatively impacting device performance and/or impose stringent requirements on process conditions. In the present application, a semiconductor device including a stacked FET is provided which can accommodate for having source/drain separating dielectric layers and/or stacked source/drain regions having a wide variety of vertical heights.

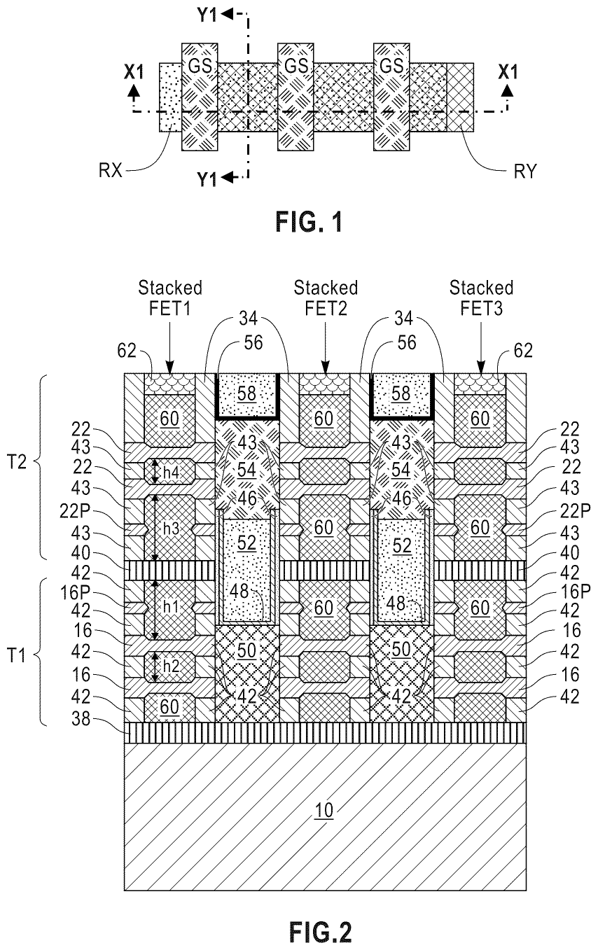

Referring first to FIG. 1, there is illustrated a device layout that can be used in the present application. The device layout illustrated in FIG. 1 includes a first active device region, RX, and a second active device region, RY. In the present application, the second active device region, RY, is stacked on top of the first active device region, RX. The device layout illustrated in FIG. 1 also includes three gate structures, GS, which are oriented parallel to each other and perpendicular to the first active device region, RX, and the second active device region, RY. Three gate structures are shown by way of one example, and as such, the present application is not limited to that number of gate structures. Also, shown is cut X1-X-1 and cut Y1-Y1. Cut X1-X1 is a cut that runs in a length wise direction through a portion of the stacked first active device region, RX, and second active device region, RY. The Y1-Y1 is a cut that runs in a length wise direction between a first gate structure and a second gate structure and it passes through a portion of the stacked first active device region, RX, and second active device region, RY; cut Y1-Y1 lies perpendicular to cut X1-X1. Notably, cut Y1-Y1 is through the source/drain area of the stacked transistors of the present application. In the remaining drawings, namely FIGS. 2-5 and 6A-6Q, only the X1-X1 cut will be illustrated.

Referring now to FIGS. 2-5, there are illustrated various semiconductor devices in accordance with the present application. Notably, each semiconductor device includes first nanosheet transistor, T1, including a plurality of vertically stacked and spaced apart first device semiconductor channel material nanosheets, each first device semiconductor channel material nanosheet 16 having a middle portion located in an active gate region and end portions located under a gate spacer 34, in which the middle portion of each first device semiconductor channel material nanosheet is thinner than the end portions of each first device semiconductor channel material nanosheet, gate structure 60 wrapping around the middle portion of each of the first device semiconductor channel material nanosheets 16, and a first device semiconductor material structure 16P vertically aligned above each end portion of the first device semiconductor channel material nanosheets and having an inner sidewall in contact with the gate structure 60. Each first device semiconductor channel material nanosheet 16 having the thinned middle portion and thicker end portions are dumb-bell shaped; note the middle portion and the end portions provide a contiguous structure. The semiconductor device further includes second nanosheet transistor, T2, stacked vertically above the first nanosheet transistor, T1. In the present application, each T2-T1 combination provides a stacked FET. Notably, each of FIGS. 2-5 includes a first stacked FET (i.e., stacked FET1), a second stacked FET (i.e., stacked FET2), and a third stacked FET (i.e., stacked FET3). The present application is not limited to the three stacked FETs as is illustrated in each of FIGS. 2-5. Instead, the present application works for one stacked FET, two stacked FETs or greater than three stacked FETs.

As illustrated in FIGS. 2-5, T2 includes a plurality of vertically stacked and spaced apart second device semiconductor channel material nanosheets, each second device semiconductor channel material nanosheet 22 having a middle portion located in the active gate region and end portions located under the gate spacer 34, in which the middle portion of each second device semiconductor channel material nanosheet is thinner than the end portions of each second device semiconductor channel material nanosheet, gate structure 60 wrapping around the middle portion of each of the second device semiconductor channel material nanosheets 22, and a second device semiconductor material structure 22P vertically aligned beneath each end portion of the second device semiconductor channel material nanosheets 22 and having an inner sidewall in contact with the gate structure 60. Each second device semiconductor channel material nanosheet 22 having the thinned middle portion and thicker end portions are dumb-bell shaped; note the middle portion and the end portions provide a contiguous structure.

The stacked FETs illustrated in FIGS. 2-5 (having the first and second semiconductor material portions under the gate spacer 34) accommodate for having source/drain separating dielectric layers 52 and/or stacked source/drain regions having a wide variety of vertical heights. The wide variety of heights can be along the same source/drain canyon or across different source/drain canyons.

In the stacked FETs illustrated in FIGS. 2-5, each or the first semiconductor material structure 16P and the second semiconductor material structure 22P is discontinuous and is not present in the active gate region. This aspect together with dumb-bell shaped semiconductor channel material nanosheets can accommodate different gate heights within T1 and T2 as shown in each of FIGS. 2-5. Notably, T1 can include a first gate height, h1, as measured from a bottom surface of middle dielectric isolation layer 40 to a middle portion of the topmost first device semiconductor channel material nanosheet which is greater than a second gate height, h2, as measured between a middle portion of adjacently stacked first device semiconductor channel material nanosheets. Similarly, T2 can include a third gate height, h3, as measured from a top surface of the middle dielectric isolation layer 40 to a middle portion of the bottommost second device semiconductor channel material nanosheet which is greater than a fourth gate height, h4, as measured between a middle portion of adjacently stacked second device semiconductor channel material nanosheets. Note that h1 can be equal to, or different than, h3, and h2 can be equal to or different than h4.

The semiconductor devices illustrated in FIGS. 2-5 further include a source/drain canyon located on each side of the first nanosheet transistor, T1, and the second nanosheet transistor, T2, See, for example, stacked FET2 shown in each of FIGS. 2-5. Each source/drain canyon includes first device source/drain region 50 and second device source/drain region 54 which are separated by source/drain separating dielectric layer 52. In some embodiments (See, for example, FIG. 2) each of the first device source/drain region 50, the source/drain separating dielectric layer 52, and the second device source/drain region 54 has a same vertical height in each source/drain canyon.

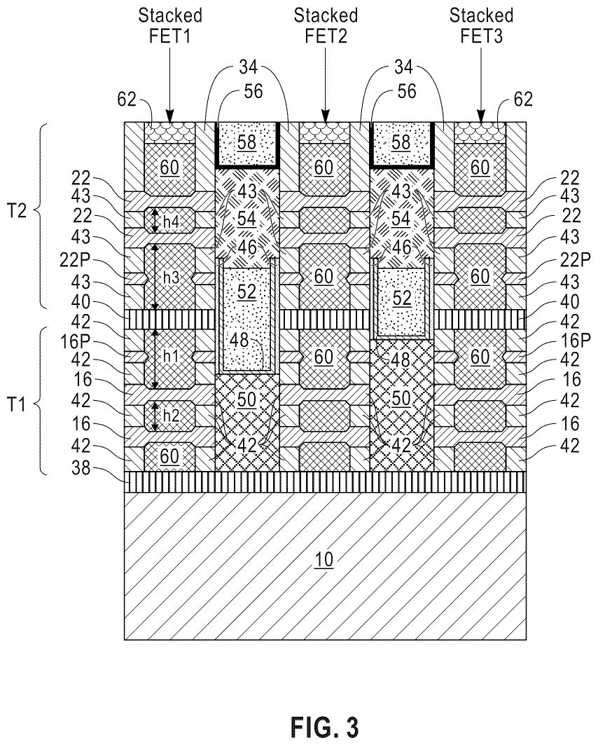

In other embodiments (see, for example, FIG. 3), each of the first device source/drain region 50 and the source/drain separating dielectric layer 52 has a different vertical height in each source/drain canyon.

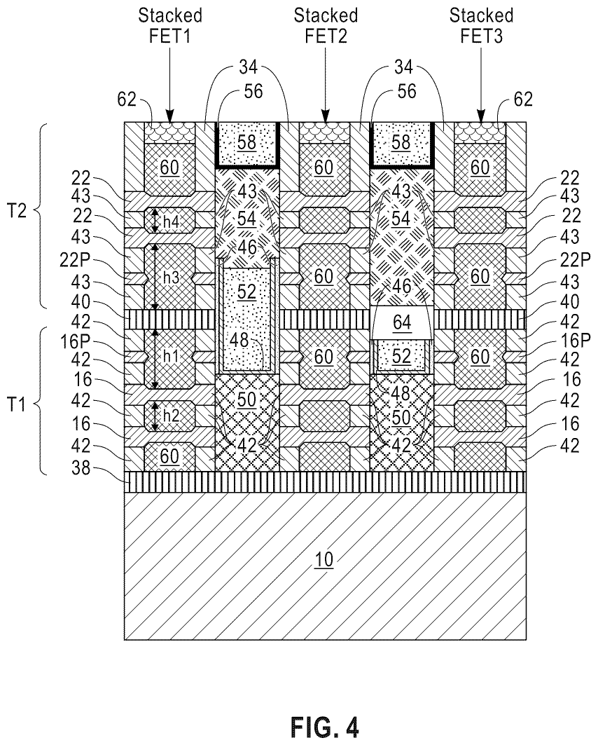

In yet other embodiments (See, for example, FIG. 4), each of the source/drain separating dielectric layer 52 and the second device source/drain region 54 has a different vertical height in each source/drain canyon. In FIG. 4, air gap 64 can be present in one of the source/drain canyons.

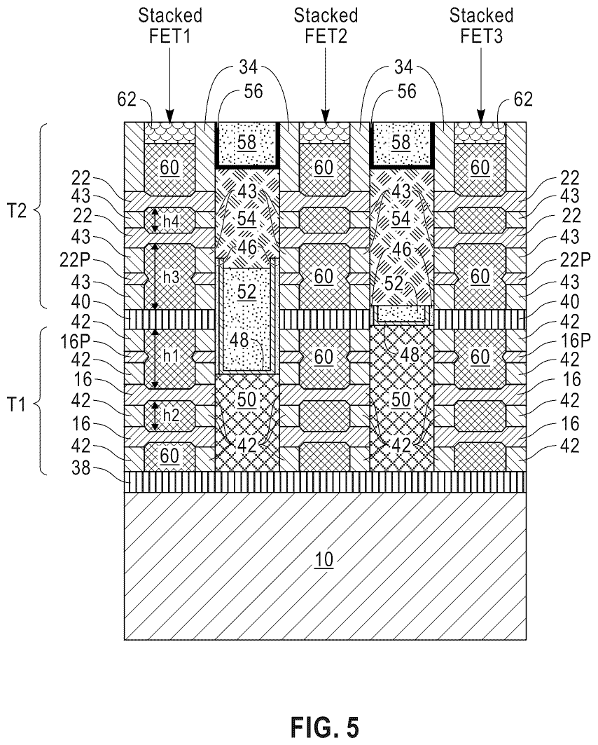

In yet further embodiments (See, for example, FIG. 5) each of the first device source/drain region 50, the source/drain separating dielectric layer 52, and the second device source/drain region 54 has a different vertical height in each source/drain canyon.

In FIGS. 2-5, the semiconductor device can include bottom dielectric isolation layer 38 located beneath the first nanosheet transistor, T1, and middle dielectric isolation layer 40 separating the plurality of vertically stacked and spaced apart first device semiconductor channel material nanosheets from the plurality of vertically stacked and spaced apart second device semiconductor channel material nanosheets. As is shown, gate structure 60 also wraps around a middle portion of the middle dielectric isolation layer 40.

In FIGS. 2-5, the semiconductor device can include blocking spacer 46 contacting an outer sidewall of both the first device semiconductor material structure 16P and the second device semiconductor material structure 22P.

In FIGS. 2-5, the semiconductor device can include first device dielectric liner 48 located on a sidewall and a bottommost surface of the source/drain separating dielectric layer 52.

In FIGS. 2-5, the semiconductor device can include first device inner spacer 42 located above and beneath each end portion of each first device semiconductor channel material nanosheets 16 and the first device semiconductor material structure 16P and second device inner spacer 43 located beneath each end portion of each second device semiconductor channel material nanosheets 22 and the second device semiconductor material structure 22P.

In some embodiments, T1 is of a first conductivity type, and T2 is of a second conductivity type, in which the first conductivity type is different from the second conducive type. Embodiments also include T1 and T2 being of a same conductivity type.

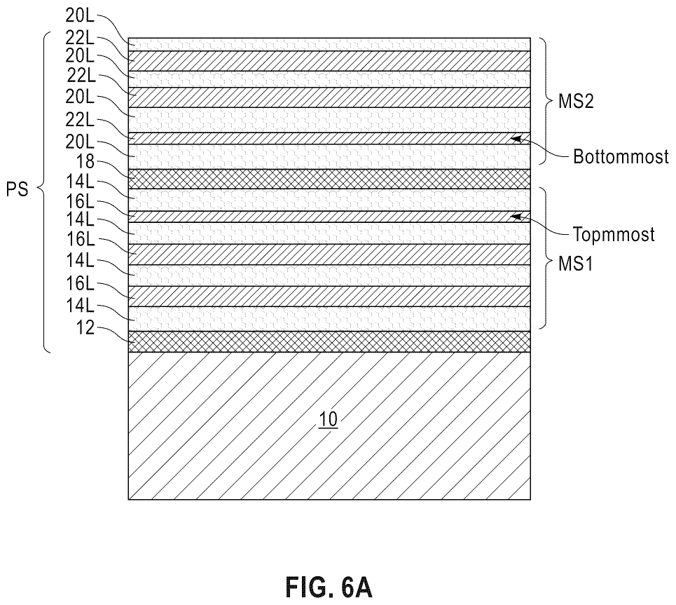

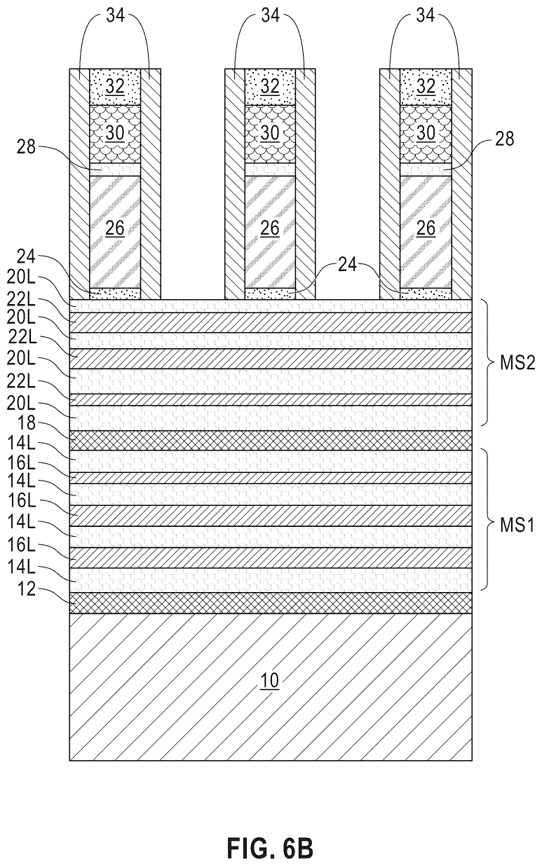

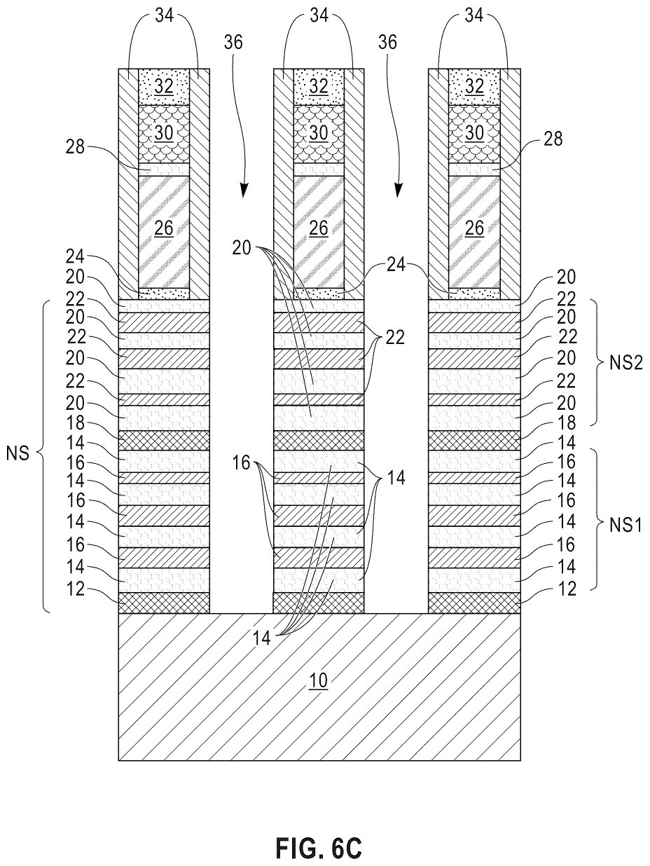

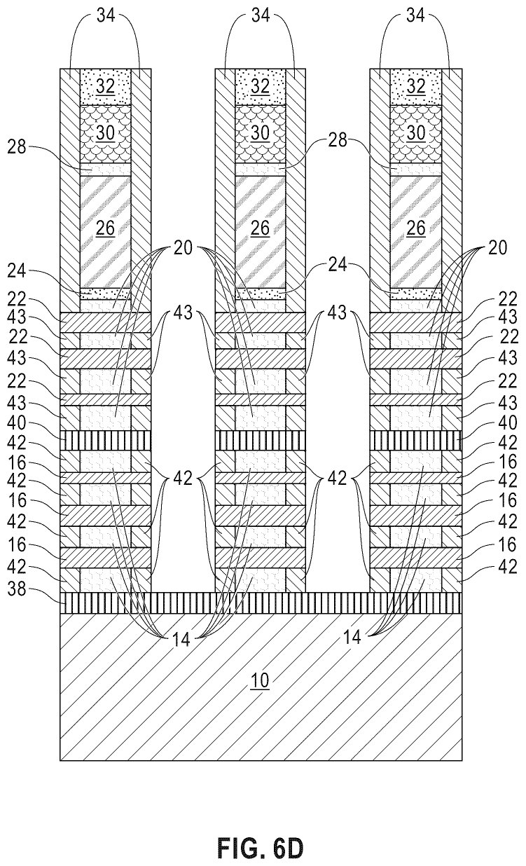

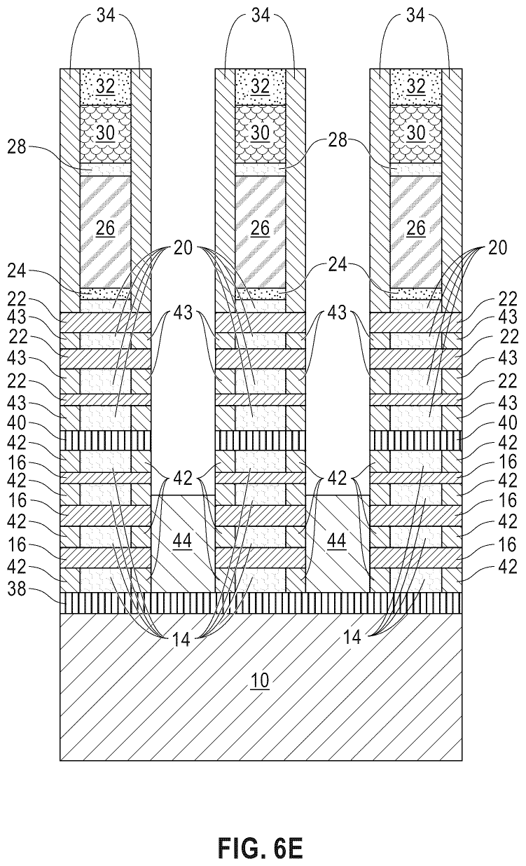

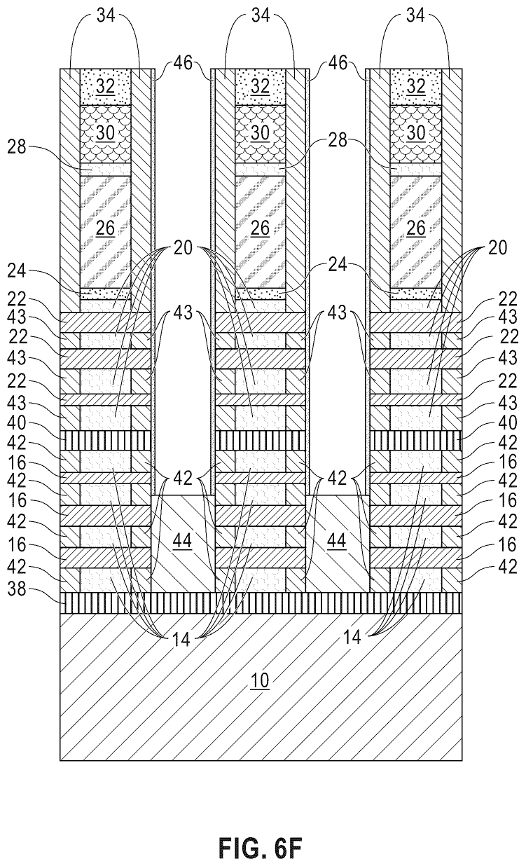

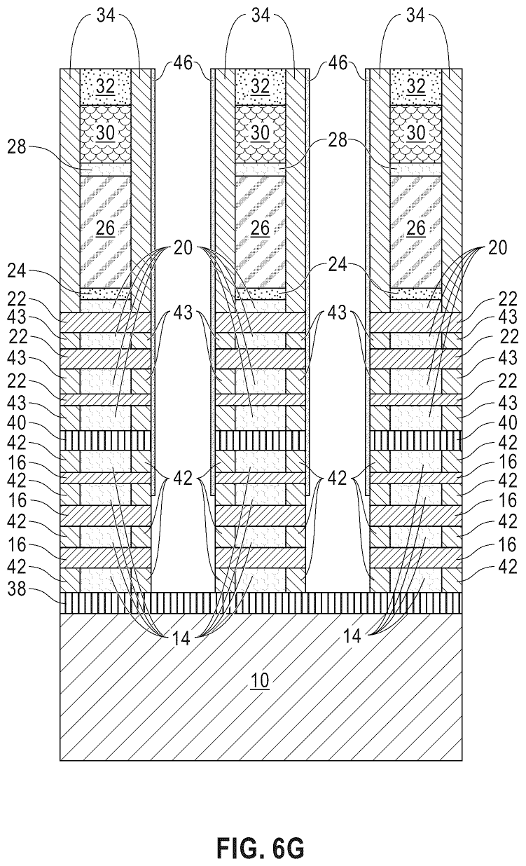

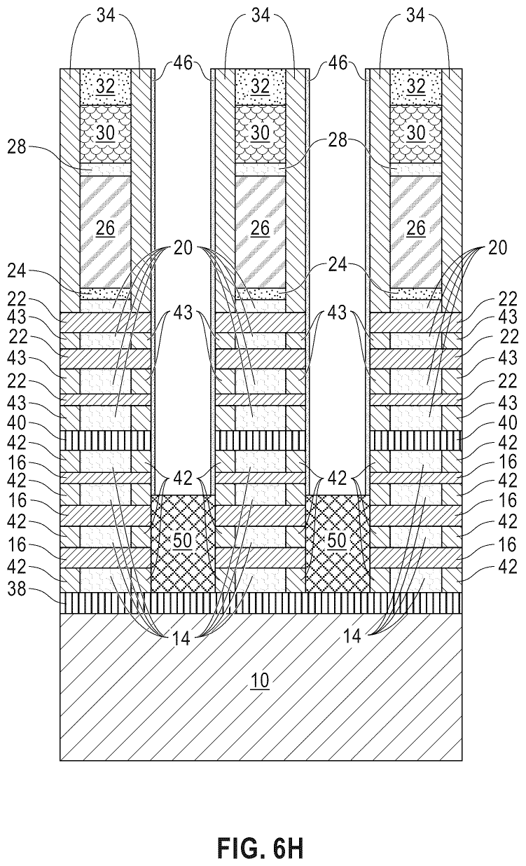

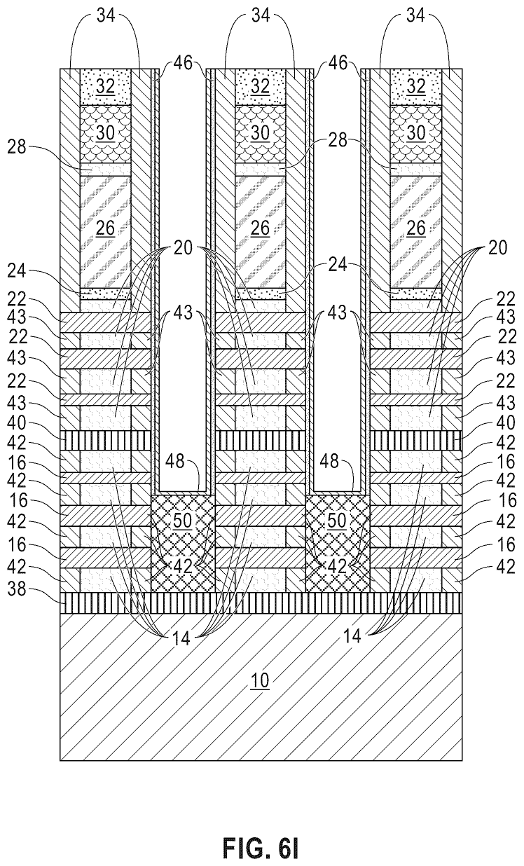

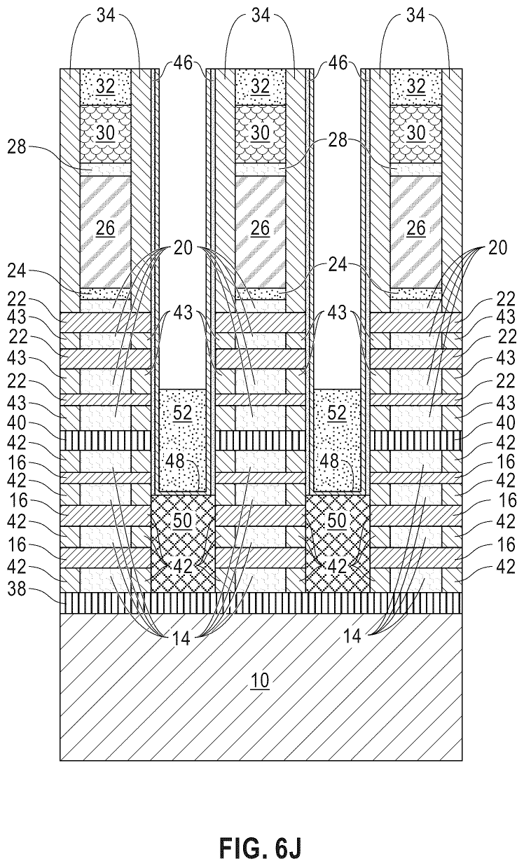

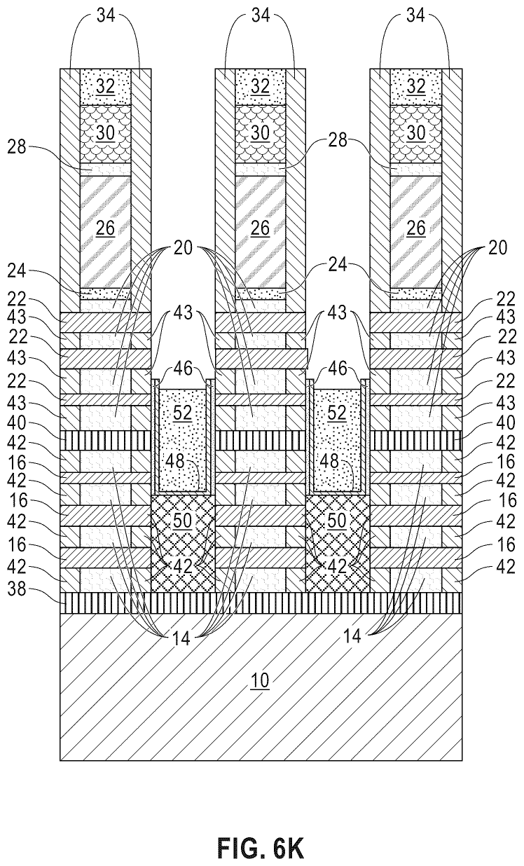

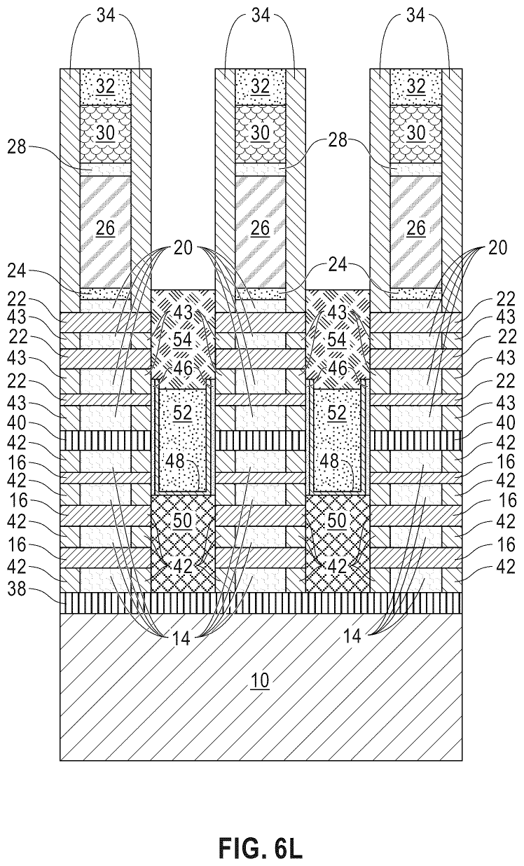

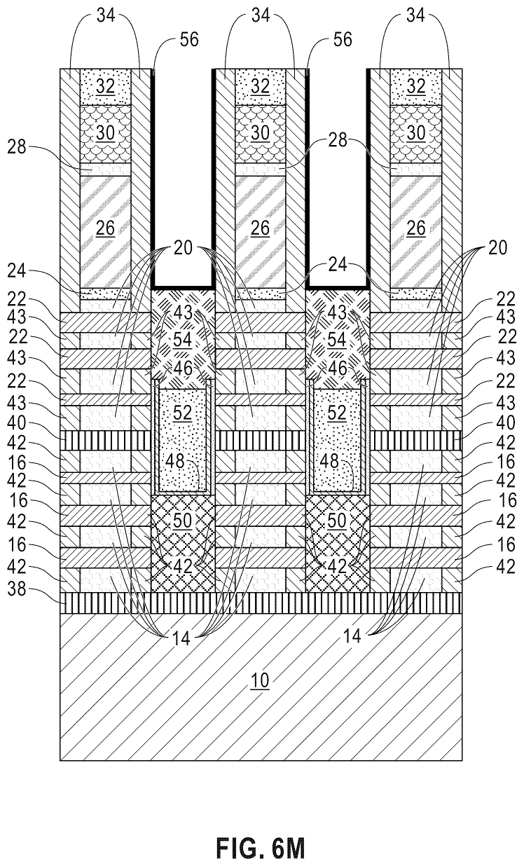

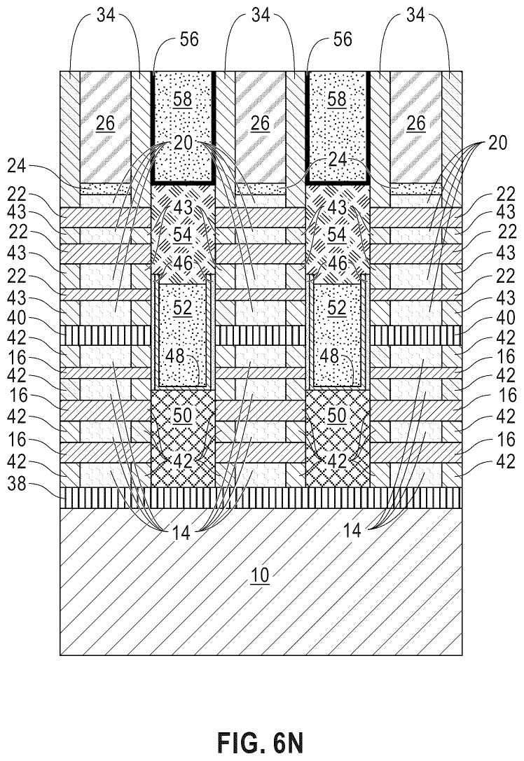

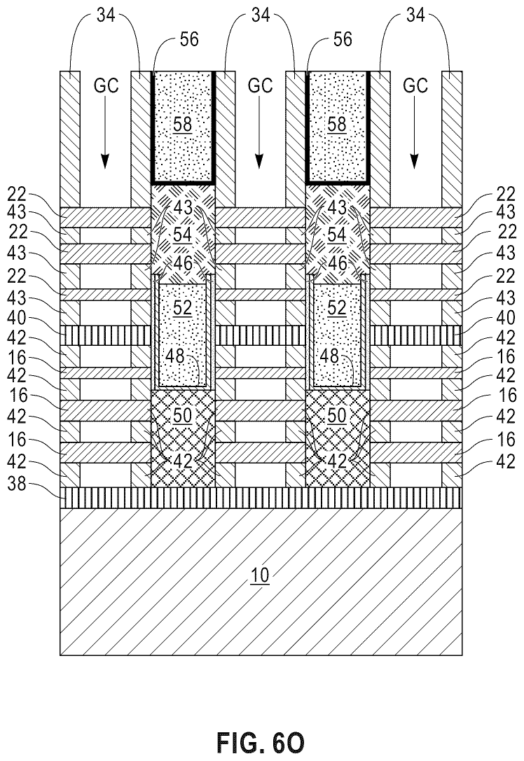

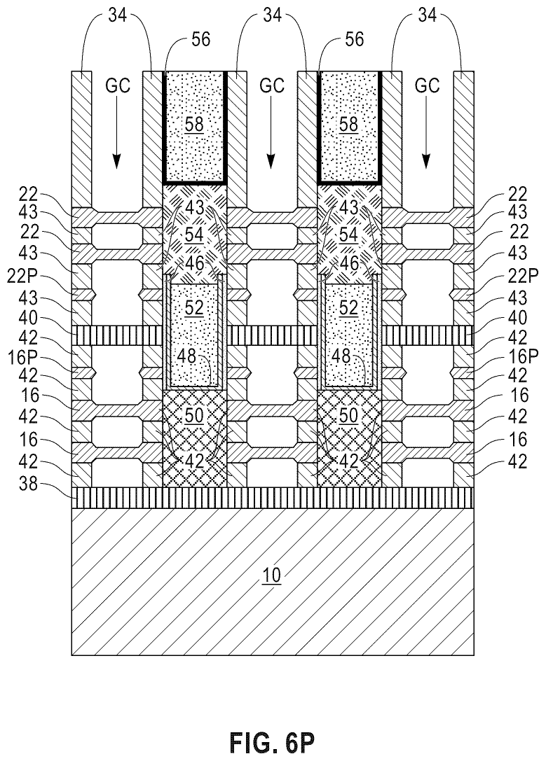

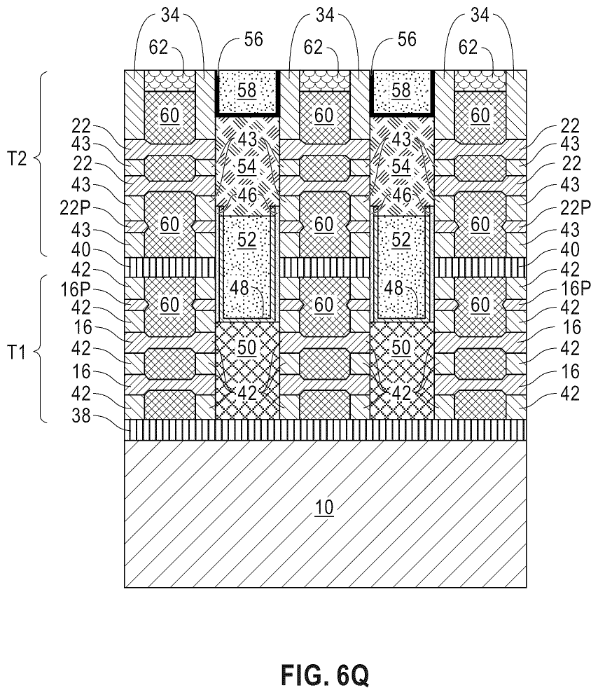

Reference will now be made to FIGS. 6A-6Q which illustrate a process flow that can be used in forming a semiconductor device in accordance with an embodiment of the present application. Notably, the process flow illustrated in FIGS. 6A-6Q can be used in providing the semiconductor device illustrated in FIG. 2. Variations in recessing of the first source/drain region 50 and/or the source/drain separating dielectric layer 52 can cause the process flow to form the semiconductor devices illustrated in FIGS. 3-5. Referring first to FIG. 6A, there is illustrated a first step of the process flow in which an exemplary structure is provided. The exemplary structure includes a semiconductor substrate 10, a first sacrificial semiconductor layer 12, a first device material stack, MS1, of alternating first device sacrificial semiconductor material layers 14L and first device semiconductor channel material layers 16L, a second sacrificial semiconductor layer 18, a second device material stack, MS2, of alternating second device sacrificial semiconductor material layers 20L and second device semiconductor channel material layers 22L.

The semiconductor substrate 10 is composed of at least one semiconductor material having semiconducting properties. Illustrative examples of semiconductor materials that can be used in providing the semiconductor substrate 10 include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments, the semiconductor substrate 10 is entirely composed of one or more semiconductor materials. In other embodiments, the semiconductor substrate 10 can include a buried dielectric layer (e.g., silicon dioxide and/or boron nitride) sandwiched between a semiconductor base layer and a semiconductor device layer.

The first sacrificial semiconductor layer 12 is composed of a first semiconductor material that is compositionally different from an uppermost semiconductor surface of the semiconductor substrate 10. In one example, the first sacrificial semiconductor layer 12 is composed of a SiGe alloy in which the germanium content is at least 45 atomic percent or greater.

As mentioned above, MS1 includes alternating first device sacrificial semiconductor material layers 14L and first device semiconductor channel material layers 16L. As is illustrated in FIG. 6A, MS1 can include “n” number of first device semiconductor channel material layers 16L and “n+1” number of first device sacrificial semiconductor material layers 14L, wherein n is an integer starting from 2, typically n is 3 or more. Each first device semiconductor channel material layer 16L is sandwiched between a bottom first device sacrificial semiconductor material layer and a top first device sacrificial semiconductor material layer. Each first device sacrificial semiconductor material layer 14L is composed of a second semiconductor material, while each first device semiconductor channel material layer 16L is composed of a third semiconductor material. In the present application, the second semiconductor material is compositionally different from the third semiconductor material, and both the second semiconductor material and the third semiconductor material are compositionally different from the first semiconductor material that provides the first sacrificial semiconductor layer 12. In some embodiments, the third semiconductor material that provides each first device semiconductor channel material layer 16L can provide high channel mobility for n-type FET devices (i.e., NFETs). In other embodiments, the third semiconductor material that provides each first device semiconductor channel material layer 16L can provide high channel mobility for p-type FET devices (PFETs). The second semiconductor material that provides each first device sacrificial semiconductor material layer 14L, and the third semiconductor material that provides each first device semiconductor channel material layer 16L can include one of the semiconductor materials mentioned above for the semiconductor substrate 10. In one example, the second semiconductor material that provides each first device sacrificial semiconductor material layer 14L is composed of a silicon germanium alloy having a germanium content from 20 atomic percent to 40 atomic percent and the third semiconductor material that provides each first device semiconductor channel material layer 16L is composed of silicon.

In the present application, a topmost first device semiconductor channel material layer present in MS1 is intentionally designed to have a thickness than is less than a thickness of the other first device semiconductor channel material layers 16L present in MS1.

The second sacrificial semiconductor layer 18 is composed of the first semiconductor material mentioned above for the first sacrificial semiconductor layer 12. In one example, the second sacrificial semiconductor layer 18 is composed of a SiGe alloy in which the germanium content is at least 45 atomic percent or greater.

As mentioned above, MS2 includes alternating second device sacrificial semiconductor material layers 20L and second device semiconductor channel material layers 22L. As is illustrated in FIG. 6A, MS2 can include “m” number of second device semiconductor channel material layers 22L and “m+1” number of second device sacrificial semiconductor material layers 20L, wherein m is an integer starting from 2, typically n is 3 or more. Each second device semiconductor channel material layer 22L is sandwiched between a bottom second device sacrificial semiconductor material layer and a top second device sacrificial semiconductor material layer. Each second device sacrificial semiconductor material layer 20L is composed of the second semiconductor material mentioned above, while each second device semiconductor channel material layer 22L is composed of a fourth semiconductor material. In the present application, the second semiconductor material is compositionally different from the fourth semiconductor material, and both the second semiconductor material and the fourth semiconductor material are compositionally different from the first semiconductor material that provides the first sacrificial semiconductor layer 12 and the second sacrificial semiconductor layer 18. The fourth semiconductor material can be compositionally the same as, or compositionally different from, the third semiconductor material. In some embodiments, the fourth semiconductor material that provides each second device semiconductor channel material layer 22L can provide high channel mobility for NFETs. In other embodiments, the fourth semiconductor material that provides each second device semiconductor channel material layer 22L can provide high channel mobility for PFETs. The fourth semiconductor material that provides each second device semiconductor channel material layer 22L can include one of the semiconductor materials mentioned above for the semiconductor substrate 10. In one example, the second semiconductor material that provides each second device sacrificial semiconductor material layer 20L is composed of a silicon germanium alloy having a germanium content from 20 atomic percent to 40 atomic percent and the fourth semiconductor material that provides each first device semiconductor channel material layer 22L is composed of silicon.

In the present application, a bottommost second device semiconductor channel material layer present in MS2 is intentionally designed to have a thickness than is less than a thickness of the other second device semiconductor channel material layers 22L present in MS2.

The first sacrificial semiconductor layer 12, MS1 (including the alternating first device sacrificial semiconductor material layers 14L and first device semiconductor channel material layers 16L), the second sacrificial semiconductor layer 18, and MS2 (including the alternating second device sacrificial semiconductor material layers 20L and second device semiconductor channel material layers 22L) are patterned layers which collectively form a patterned stack, PS, that is formed on the semiconductor substrate 10 by deposition of each layer, followed by lithographically patterning the as-deposited layers. Although a single patterned stack, PS, is described and illustrated, a plurality of patterned stacks can be formed. Each patterned stack will be used in defining an active device area in which a stacked FET will be formed. The deposition of each layer can include, for example, chemical vapor deposition (CVD), plasma enhanced chemical vapor deposition (PECVD) and/or epitaxial growth. Typically, the first sacrificial semiconductor layer 12 is formed by epitaxial growth. Throughout the present application, the terms “epitaxial growth” or “epitaxially growing” mean the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450° C. to 900° C. Although higher temperature typically results in faster deposition, the faster deposition may result in crystal defects and film cracking.

Throughout the present application, lithographic patterning denotes a patterning process in which a photoresist material is first formed on a layer or structure that needs to be patterned. The photoresist material can be formed by a deposition process including, for example, CVD, PECVD or spin-on coating. The as-deposited photoresist material is then subjected to a desired pattern of irradiation. The exposed photoresist material is then developed utilizing a conventional resist developer. The etch used in the patterning process can include, for example, a dry etching process, a wet chemical etching process or a combination of dry etching and wet chemical etching. Dry etching can include reactive ion etching (RIE), ion beam etching (IBE) or plasma etching. Although a single patterned stack is described and illustrated, a plurality of patterned stacks can be formed.

Referring now to FIG. 6B, there is illustrated the exemplary structure of FIG. 6A after forming a sacrificial gate structure 26 and a gate spacer 34. In some embodiments, a sacrificial dielectric layer 24 and/or a sacrificial gate cap can be used. FIG. 6B illustrates an embodiment in which both the sacrificial dielectric layer 24 and sacrificial gate cap can be used. In the illustrated embodiment, the sacrificial gate cap is a tri-layered structure which includes a first sacrificial gate cap layer 28, a second sacrificial gate cap layer 30 and a third sacrificial gate cap layer 32. In some embodiments, the sacrificial gate cap includes only a single layered structure or a bilayer structure. In the illustrated embodiment, three sacrificial gate structures 26 are shown by way of an example. The present application is not limited to any number of sacrificial gate structures 26 so long as at least one sacrificial gate structure 26 is formed. In the present application, each sacrificial gate structure 26 and the gate spacer 34 straddle the patterned stack, PS; i.e., each sacrificial gate structure 26 and gate spacer 34 are located along sidewalls and a topmost surface of the patterned stack, PS.

When present, the sacrificial dielectric layer 24 is composed of a sacrificial dielectric material such as, for example, silicon dioxide. The sacrificial dielectric layer 24 is optional and thus can omitted in some embodiments of the present application.

The sacrificial gate structure 26 includes at least a sacrificial gate material. The sacrificial gate material can be composed of, for example, polysilicon, amorphous silicon, amorphous silicon germanium or amorphous germanium.

The sacrificial gate cap is composed of any dielectric hard mask material such as, for example, silicon nitride, silicon oxide, and/or silicon oxynitride. In the embodiment illustrated in FIG. 6B, the first sacrificial gate cap layer 28 is composed of a first dielectric hard mask material, the second sacrificial gate cap layer 30 is composed of a second dielectric hard mask material, and the third sacrificial gate cap layer 32 is composed of a third dielectric hard mask material. In such an embodiment, the second dielectric hard mask material is compositionally different from both the first dielectric hard mask material and the third dielectric hard mask material. The first and third dielectric hard mask materials can be compositionally the same, or compositionally different from each other. In one example, the first dielectric hard mask material is composed of silicon dioxide, the second dielectric hard mask is composed of silicon nitride, and the third dielectric hard mask material is composed of silicon dioxide.

The gate spacer 34 is composed of a gate spacer material such as, for example, silicon dioxide, SiN, SiBCN, SiOCN or SiOC. The gate spacer 34 is present along the sidewall of the sacrificial gate structure 26.

The exemplary structure shown in FIG. 6B can be formed by depositing (e.g., CVD, PECVD, PVD or ALD) a blanket layer of sacrificial dielectric material (if the same is present), followed by depositing (e.g., CVD, PECVD, ALD or PVD) a blanket layer of the sacrificial gate material, followed by depositing (e.g., CVD, PECVD, ALD or PVD) a blanket layer of each of the first, second and third dielectric hard mask materials, if the same are present. Lithographic patterning is then used form the sacrificial dielectric layer 24 (if present), the sacrificial gate structure 26, the first sacrificial gate cap layer 28, the second sacrificial gate cap layer 30, and the third sacrificial gate cap layer 32 (if each is present). Gate spacer 34 is then formed by deposition of the gate spacer material, followed by a spacer etch.

Referring now to FIG. 6C, there is illustrated exemplary structure of FIG. 6B after patterning the second device material stack MS2, the second sacrificial semiconductor layer 18, the first device material stack MS1 and the first sacrificial semiconductor layer 12 utilizing the sacrificial gate structure 26 and the gate spacer 34 as a combined etch mask; in the illustrated embodiment, the tri-layered gate cap structure can also be part of the etch mask. The patterning includes an etch which converts the patterned stack, PS, into at least one nanosheet-containing stack, NS. In the illustrated embodiment, three nanosheet-containing stacks are formed. The etch used in forming the at least one nanosheet-containing stack, NS, can include any dry etching process and/or chemical wet etching process. Typically, a RIE is used in forming the at least one nanosheet-containing stack, NS. The etch forms a source/drain canyon (i.e., opening) 36 located adjacent to each nanosheet-containing stack, NS. As is shown, some of the source/drain canyons 36 are located between a neighboring pair of nanosheet-containing stacks, NS. Each source/drain canyon 36 physically exposes the uppermost semiconductor surface of semiconductor substrate 10.

Each nanosheet-containing stack, NS, which is formed includes a remaining (i.e., non-etched) portion of MS2, a remaining (i.e., non-etched) portion of the second sacrificial semiconductor layer 18, a remaining (i.e., non-etched) portion of MS1 and a remaining (i.e., non-etched) portion of the first sacrificial semiconductor layer 12. Within each nanosheet-containing stack, NS, the non-etched portion of MS2 is referred to as second nanosheet stack, NS2, while the non-etched portion of MS1 is referred to as first nanosheet stack, NS1. The first nanosheet stack, NS1, includes a remaining (i.e., non-etched) portion of the alternating first device sacrificial semiconductor material layers 14L and first device semiconductor channel material layers 16L. The remaining (i.e., non-etched) portion of each first device sacrificial semiconductor material layer 14L is now referred to as a first device sacrificial semiconductor material nanosheet 14, and the remaining (i.e., non-etched) portion of each first device semiconductor channel material layer 16L is now referred to as a first device semiconductor channel material nanosheet 16. The second nanosheet stack, NS2, includes a remaining (i.e., non-etch) portion of the alternating second device sacrificial semiconductor material layers 20L and second device semiconductor channel material layers 22L. The remaining (i.e., non-etched) portion of each second device sacrificial semiconductor material layer 20L is now referred to as a second device sacrificial semiconductor material nanosheet 20, and the remaining (i.e., non-etched) portion of each second device semiconductor channel material layer 22L is now referred to as a second device semiconductor channel material nanosheet 22. Note that the topmost first device semiconductor channel material nanosheet is thinner than the remaining first device semiconductor channel material nanosheet 16, and the bottommost second device semiconductor channel material nanosheet is thinner than the remaining second device semiconductor channel material nanosheet 22.

In the present application, NS2 is located above NS1 and NS1 and NS2 are spaced apart by the remaining (i.e., non-etched) portion of the second sacrificial semiconductor layer 18. As is illustrated, NS1 lands on the remaining (i.e., non-etched) portion of the first sacrificial semiconductor layer 12.

Referring now to FIG. 6D, there is illustrated the exemplary structure of FIG. 6C after forming first device inner spacers 42, second device inner spacers 43, a bottom dielectric isolation layer 38 and a middle dielectric isolation layer 40. The forming of the first device inner spacers 42 and the second device inner spacers 43 includes recessing each first device sacrificial semiconductor material nanosheet 14 and each second device sacrificial semiconductor material nanosheet 20. The recessing includes a lateral etching process that is selective in partially removing the second semiconductor material that provides each first device sacrificial semiconductor material nanosheet 14 and each second device sacrificial semiconductor material nanosheet 20. A gap is formed at each of the ends of each recessed first device sacrificial semiconductor material nanosheet 14 and at each of the ends of each recessed second device sacrificial semiconductor material nanosheets 20. The forming of the first device inner spacers 42 and the second device inner spacers 43 continues by depositing (CVD, PECVD, or ALD) a layer of inner dielectric spacer material in each of the gaps and along the sidewall of the nanosheet-containing stack, NS. The inner dielectric spacer material can include, but is not limited to, silicon dioxide, SiN, SiBCN, SiOCN or SiOC. After depositing the layer of inner dielectric spacer material, an isotropic etch back process is performed on the layer of inner dielectric spacer material. This isotropic etch back process removes the layer of inner dielectric spacer material that is present on the sidewalls of the nanosheet-containing stack, NS, while maintaining the layer of inner dielectric spacer material in each gaps. The maintained layer of inner dielectric spacer material within each of the gaps provides the first device inner spacers 42 and the second device inner spacers 43. The first device inner spacers 42 and the second device inner spacers 43 are formed simultaneously and thus are composed of a same inner dielectric spacer material.

Either prior to, or after, forming the first device inner spacers 42 and the second device inner spacers 43, the bottom dielectric isolation layer 38 and the middle dielectric isolation layer 40 can be formed by replacing the remaining (i.e., non-etched) portion of the first sacrificial semiconductor layer 12 and the remaining (i.e., non-etched) portion of the second sacrificial semiconductor layer 18 with a dielectric isolation material; during this replacement process each nanosheet-containing stack, NS, is anchored in place by at least the sacrificial gate structure 26 and the gate spacer 34. The dielectric isolation material that provides the bottom dielectric isolation layer 38 and the middle dielectric isolation layer 40 is typically compositionally different from the gate spacer 34 as well as the first device inner spacers 42 and the second device inner spacers 43. The dielectric isolation material can include, for example, SiBCN, SiOCN or SiOC. The replacing of the remaining (i.e., non-etched) portion of the first sacrificial semiconductor layer 12 and the remaining (i.e., non-etched) portion of the second sacrificial semiconductor layer 18 with dielectric isolation material includes an etch, followed by deposition of a dielectric isolation material and an isotropic etch. In the present application, the middle dielectric isolation layer 40 has a same length as each of the semiconductor channel material nanosheets present in NS1 and NS2, and bottom dielectric isolation layer 38 extends along the uppermost semiconductor surface of the semiconductor substrate 10 and beneath each nanosheet-containing stack, NS.

Referring now to FIG. 6E, there is illustrated the exemplary structure of FIG. 6D after forming a sacrificial placeholder material layer 44 in the source/drain canyon 36. The sacrificial placeholder material layer 44 can be composed of a gap fill dielectric material such as, for example, spin-on glass (SOG). The sacrificial placeholder material layer 44 can be formed by filling (via a deposition process) the source/drain canyon 36 with the gap fill dielectric material, followed by a partial recess etch that reduced the height of the as deposited gap fill dielectric material. The sacrificial placeholder material layer 44 lands on a portion of the bottom dielectric isolation layer 38 and has a height that is located beneath a bottommost surface of the topmost first device semiconductor channel material nanosheet 16 which is thinner than the remaining first device semiconductor channel material nanosheets 16.

Referring now to FIG. 6F, there is illustrated the exemplary structure of FIG. 6E after forming a blocking spacer 46 in the source/drain canyon 36 and on top of the sacrificial placeholder material layer 44. The blocking spacer 46 is present along a sidewall of the nanosheet-containing stack, NS, which is not protected by the sacrificial placeholder material layer 44 and along a sidewall of the gate spacer 34. In some embodiments, the blocking spacer 46 can be composed of a single dielectric spacer material which is compositionally different from the inner dielectric spacer material and the spacer material that provides the gate spacer 34. In one example, the blocking spacer 46 is composed of silicon dioxide. In other embodiments, the blocking spacer 46 is a multilayered spacer (such as a bilayer blocking spacer) that is composed of at least two different dielectric spacer materials. In one example, the blocking spacer 46 is a bilayer spacer which is composed of an inner layer of silicon oxide, and an outer layer composed of silicon nitride. The blocking spacer 46 can be formed by deposition, followed by a recess etch. The deposition can include a single deposition process or multiple deposition processes can be used in cases in which the blocking spacer 46 is a multilayered spacer.

Referring now to FIG. 6G, there is illustrated the exemplary structure of FIG. 6F after removing the sacrificial placeholder material layer 44. The sacrificial placeholder material layer 44 can be removed utilizing an etching process that is selective in removing the sacrificial placeholder material layer 44. The etching process that removes the sacrificial placeholder material layer 44 does not remove the blocking spacer 46. The removal of the sacrificial placeholder material layer 44 physically exposes an end sidewall of the first device semiconductor channel material nanosheets 16 of NS1 that are located beneath the topmost first device semiconductor channel material nanosheet 16. In the illustrated, the bottommost two first device semiconductor channel material nanosheets 16 of NS1 have end sidewalls that are physically exposed, while the topmost first device semiconductor channel material nanosheet 16 of NS1 is protected by the blocking spacer 46.

Referring now to FIG. 6H, there is illustrated the exemplary structure of FIG. 6G after forming a first device source/drain region 50 at a bottom portion of the source/drain canyon 36. In the present application, a first device source/drain region 50 is formed adjacent to opposing sides of each nanosheet-containing stack, NS. Each first device source/drain region 50 is formed outward from each of the physically exposed end sidewalls of the first device semiconductor channel material nanosheets 16 of NS1 that are not protected by the blocking spacer 46, and on a topmost surface of the bottom dielectric isolation layer 38. Each first device source/drain region 50 is formed by an epitaxial growth process, as defined above. As used herein, a “source/drain” region can be a source region or a drain region depending on subsequent wiring and application of voltages during operation of the FET. Each first device source/drain region 50 is composed of a fifth semiconductor material and a first dopant. The fifth semiconductor material that provides each first source/drain region 50 can be compositionally the same as, or compositionally different from, the third semiconductor material that provides the first device semiconductor channel material nanosheets 16. The first dopant can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each first device source/drain region 50 can have a dopant concentration of from 4×10²⁰ atoms/cm³ to 3×10²¹ atoms/cm³. In one example, each first device source/drain region 50 is composed of phosphorus doped silicon.

Referring now to FIG. 6I, there is illustrated the exemplary structure of FIG. 6H after forming a first device dielectric liner 48 in the source/drain canyon 36 and on top of the first device source/drain region 50; the first device dielectric liner 48 is formed on an entirety of the topmost surface of the first device source/drain region 50. The first device dielectric liner 48 is formed along a sidewall of the blocking spacer 46 that is present in the source/drain canyon 36. The first device dielectric liner 48 is composed of a first dielectric liner material. The first dielectric liner material is compositionally different from the dielectric spacer material that provides the blocking spacer 46. In one example, the first device dielectric liner 48 is composed of silicon nitride. The first device dielectric liner 48 can be formed by deposition of a blanket layer of first dielectric liner material, followed by a planarization process such as, for example, chemical mechanical planarization (CMP) to remove the any portion of the blanket layer of first dielectric liner material that is formed outside of the source/drain canyon 36.

Referring now to FIG. 6J, there is illustrated the exemplary structure of FIG. 6I after forming a source/drain separating dielectric layer 52 in the source/drain canyon 36 and on top of the first dielectric liner 48. The source/drain separating dielectric layer 52 is composed of a dielectric material that is compositionally different from the first dielectric liner material that provides the first device dielectric liner 48. In one example, the source/drain separating dielectric layer 52 is composed of silicon dioxide. The source/drain separating dielectric layer 52 can be formed utilizing a deposition process, followed by a recess etch. The source/drain separating dielectric layer 52 typically, but not necessary always, has a height that extends above a topmost surface of the bottommost second device sacrificial semiconductor material nanosheet 20 of NS2. In the illustrated embodiment, the source/drain separating dielectric layer 52 has a height that extends between the bottommost second device semiconductor channel material nanosheet and the next nearest second device semiconductor channel material nanosheet.

Referring now to FIG. 6K, there is illustrated the exemplary structure of FIG. 6J after recessing the blocking spacer 46 and the first device dielectric liner 48. Each of the blocking spacer 46 and the first device dielectric liner 48 is recessed such that the remaining blocking spacer 46 and the first device dielectric liner 48 have topmost surfaces that are substantially coplanar with each other; the topmost surface of the remaining blocking spacer 46 and the first device dielectric liner 48 can be substantially coplanar with, or above, a topmost surface of the source/drain separating dielectric layer 52. The blocking spacer 46 and the first device dielectric liner 48 can be recessed utilizing one or more recess etching process. The recessing of the blocking spacer 46 and the first device dielectric liner 48 physically exposes an end sidewall of all, or at least some of, the second device semiconductor channel material nanosheets 22. In the illustrated embodiment, the recessed blocking spacer 46 and the recessed first device dielectric liner 48 are present on the end sidewall of the bottommost second device semiconductor channel material nanosheet 22, while the end sidewall of the remaining second device semiconductor channel material nanosheets 22 of NS2 are physically exposed.

Referring now to FIG. 6L, there is illustrated the exemplary structure of FIG. 6K after forming a second device source/drain region 54 on top of source/drain separating dielectric layer 52. In the present application, a second device source/drain region 54 is formed adjacent to opposing sides of each nanosheet-containing stack, NS. Each second device source/drain region 54 is formed outward from each of the physically exposed end sidewalls of the second device semiconductor channel material nanosheets 22 of NS2. Each second device source/drain region 54 is formed by an epitaxial growth process, as defined above. Each second device source/drain region 54 is composed of a sixth semiconductor material and a second dopant. The sixth semiconductor material that provides each second source/drain region 54 can be compositionally the same as, or compositionally different from, the fourth semiconductor material that provides the second device semiconductor channel material nanosheets 22. The second dopant can be of a same or different conductivity type dopant as the first dopant. When the second dopant is of the same conductivity type as the first dopant, the first and second dopants can be compositionally the same or compositionally different. In one example, the first dopant is n-type, and the second conductivity dopant is p-type. In such an embodiment, the second device semiconductor channel material nanosheets 22 of NS2 and the second device source/drain regions 54 provide components of an NFET, while the first device semiconductor channel material nanosheets 16 of NS1 and the first device source/drain regions 50 provide components of a PFET. In another example, the first dopant is p-type, and the second dopant is n-type. In such an embodiment, the second device semiconductor channel material nanosheets 22 of NS2 and the second device source/drain regions 54 provide components of a PFET, while the first device semiconductor channel material nanosheets 16 of NS1 and the first device source/drain regions 50 provide components of an NFET. In yet another embodiment, the first dopant and the second dopant are both n-type. In such an embodiment, the second device semiconductor channel material nanosheets 22 of NS2 and the second device source/drain regions 54 provide components of an NFET, while the first device semiconductor channel material nanosheets 16 of NS1 and the first device source/drain regions 50 provide components of another NFET. In yet a further embodiment, the first dopant and the second dopant are both p-type. In such an embodiment, the second device semiconductor channel material nanosheets 22 of NS2 and the second device source/drain regions 54 provide components of a PFET, while the first device semiconductor channel material nanosheets 16 of NS1 and the first device source/drain regions 50 provide components of another PFET. Each second device source/drain region 54 can have a dopant concentration of from 4×10²⁰ atoms/cm³ to 3×10²¹ atoms/cm³.

Referring now to FIG. 6M, there is illustrated the exemplary structure of FIG. 6L after forming a second device dielectric liner 56 in the source/drain canyon 36 and on top of the second device source/drain region 54; the second device dielectric liner 56 is formed on an entirety of the topmost surface of the second device source/drain region 54. The second device dielectric liner 56 is formed along a sidewall of the gate spacer 34. The second device dielectric liner 56 is composed of a second dielectric liner material which can be compositionally the same as, or compositionally different from, the first dielectric liner material. The second dielectric liner material is compositionally different from the dielectric spacer material that provides the gate spacer 34. In one example, the second device dielectric liner 56 is composed of silicon nitride. The second device dielectric liner 56 can be formed by deposition of a blanket layer of second dielectric liner material, followed by a planarization process such as, for example, chemical mechanical planarization (CMP) to remove the any portion of the blanket layer of second dielectric liner material that is formed outside of the source/drain canyon 36.

Referring now to FIG. 6N, there is illustrated the exemplary structure of FIG. 6M after forming ILD layer 58 on the second device dielectric liner 56. The ILD layer 58 fills in an uppermost portion of the source/drain canyon 36. The ILD layer 58 is composed of an ILD material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 3.9 (all dielectric constants mentioned herein are measured in a vacuum unless otherwise noted). The ILD material that provides ILD layer 58 can be formed by a deposition process including, but not limited to, CVD, PECVD or spin-on coating. A planarization process such as, for example, chemical mechanical polishing (CMP) follows the deposition process. The planarization process used in providing the ILD layer 58 can remove the sacrificial gate cap and an upper portion of the gate spacer 34 that was present along the sidewalls of the sacrificial gate cap. The sacrificial gate structure 26 is revealed after forming the ILD layer 58.

Referring now to FIG. 6O, there is illustrated the exemplary structure of FIG. 6N after removing the sacrificial gate structure 26 and releasing the second device semiconductor channel material nanosheets 22 and the first device semiconductor channel material nanosheets 16. If present, the sacrificial dielectric layer 24 is removed prior to releasing the second device semiconductor channel material nanosheets 22 and the first device semiconductor channel material nanosheets 16. The sacrificial gate structure 26 and, if present, the sacrificial dielectric layer 24 are removed to reveal the nanosheet-containing stack, NS. The sacrificial gate structure 26 and, if present, the sacrificial dielectric layer 24 can be removed utilizing at least one material removal process such as, for example, etching, which is selective in removing the sacrificial gate structure 26 and, if present, the sacrificial dielectric layer 24. In some embodiments, a first etch is used to remove the sacrificial gate structure 26 and a second etch is used to remove the sacrificial dielectric layer 24.

After removing the sacrificial gate structure 26 and, if present, the sacrificial dielectric layer 24, each first device sacrificial semiconductor material nanosheet 14 and each second device sacrificial semiconductor material nanosheet 20 are removed to suspend a middle portion of the following: each first device semiconductor channel material nanosheet 16, the middle dielectric isolation layer 40, and each second device semiconductor channel material nanosheet 22. The removal of each first device sacrificial semiconductor material nanosheet 14 and each second device sacrificial semiconductor material nanosheet 20 is performed utilizing any material removal process such as, for example, etching, which is selective in removing the second semiconductor material that was used in providing the first device sacrificial semiconductor material nanosheets 14 and the second device sacrificial semiconductor material nanosheets 20. The removal of the first device sacrificial semiconductor material nanosheets 14 and the second device sacrificial semiconductor material nanosheets 20 forms a gate cavity, GC. The gate cavity defines a gate active area.

Referring now to FIG. 6P, there is illustrated the exemplary structure of FIG. 6O after performing a semiconductor channel material nanosheet thinning process. The semiconductor channel material nanosheet thinning process includes a wet etch. In some embodiments, a single oxidation and etch step (or successive oxidation and etching steps) can be employed to thin the semiconductor channel material nanosheets present in NS. The semiconductor channel material nanosheet thinning process can provide first device semiconductor channel material nanosheets 16 and second device semiconductor channel material nanosheet 22 that are dumb-bell shaped. That is, the semiconductor channel material nanosheet thinning process can provide first device semiconductor channel material nanosheets 16 and second device semiconductor channel material nanosheet 22 in which a middle portion of semiconductor channel material nanosheets that is present in the active gate region has a thickness that is less than end portion of the semiconductor channel material nanosheets (the end portions are located beneath the gate spacer 34).

In the present application, the semiconductor channel material nanosheet thinning process completely remove the middle portion of the topmost first device semiconductor channel material nanosheets and the bottommost second device semiconductor channel material nanosheet which are both derived from thin semiconductor channel material layers leaving behind an end portion of topmost first device semiconductor channel material nanosheets and the bottommost second device semiconductor channel material nanosheet that are located between vertically overlying inner spacers. The remaining end portion of the topmost first device semiconductor channel material nanosheet can be referred to herein as a first device semiconductor material structure 16P. The remaining end portion of the bottommost device semiconductor channel material nanosheet can be referred to herein as a second device semiconductor material structure 22P.

The dumb-bell shaped semiconductor channel material nanosheets provide a middle portion in the active gate region that is thinner than the end portions which are located beneath the gate spacer 34 and are not present in the active gate region. The removal of the middle portion of some of the semiconductor channel material nanosheets provides for a greater volume of the gate cavity between the dumb-bell shaped semiconductor channel material nanosheets and it accommodates the height variations of the first device source/drain region 50 and/or the source/drain separating dielectric layer 52 and/or the second device source/drain region 54 present in the source/drain canyons 36.

Referring now to FIG. 6Q, there is illustrated the exemplary structure of FIG. 6P after forming a gate structure 60 and a gate cap 62. The gate structure 60 wraps around a middle portion of each first device semiconductor channel material nanosheet 16, the middle dielectric isolation layer 40, and each second device semiconductor channel material nanosheet 22. The gate structure 60 includes a gate dielectric material and a gate electrode, both of which are not separately shown, but intended to be within the region defined by the gate structure 60. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structure 60 can be formed by deposition, followed by planarization.

In the present application, T1 and T2 can be of a same conductivity type (n-type or p-type) or they can be of opposite conductivity types (i.e., p-type or n-type). In the present application, the gate structure 60 that is wrapped around the first device semiconductor channel material nanosheets 14, and the first device source/drain region 50 are components of the first FET, T1, and the gate structure 60 that is wrapped around the second device semiconductor channel material nanosheets 22, and the second device source/drain region 54 are components of the second FET, T2. In the present application, the second FET is stacked above the first FET, and the first FET is isolated from the second FET by the middle dielectric isolation layer 40. In this embodiment, the gate structure 60 directly contacts the middle dielectric isolation layer 40 as shown in 6Q.

After forming the gate structure 60, the gate structure 60 can be optionally recessed and a gate cap 62 can be formed on top of the recessed gate structure as shown in FIG. 6Q. The gate cap 62 is composed of a hard mask material as defined above. The gate cap 62 can be formed by deposition of a hard mask material, followed by a planarization process.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a first nanosheet transistor comprising a plurality of vertically stacked and spaced apart first device semiconductor channel material nanosheets, each first device semiconductor channel material nanosheet having a middle portion located in an active gate region and end portions located under a gate spacer, wherein the middle portion of each first device semiconductor channel material nanosheet is thinner than the end portions of each first device semiconductor channel material nanosheet, a gate structure wrapping around the middle portion of each of the first device semiconductor channel material nanosheets, and a first device semiconductor material structure vertically aligned above each end portion of the first device semiconductor channel material nanosheets and having an inner sidewall in contact with the gate structure; and
a second nanosheet transistor stacked vertically above the first nanosheet transistor and comprising a plurality of vertically stacked and spaced apart second device semiconductor channel material nanosheets, each second device semiconductor channel material nanosheet having a middle portion located in the active gate region and end portions located under the gate spacer, wherein the middle portion of each second device semiconductor channel material nanosheet is thinner than the end portions of each second device semiconductor channel material nanosheet, the gate structure wrapping around the middle portion of each of the second device semiconductor channel material nanosheets, and a second device semiconductor material structure vertically aligned beneath each end portion of the second device semiconductor channel material nanosheets and having an inner sidewall in contact with the gate structure.

2. The semiconductor device of claim 1, further comprising a bottom dielectric isolation layer located beneath the first nanosheet transistor.

3. The semiconductor device of claim 1, further comprising a middle dielectric isolation layer separating the plurality of vertically stacked and spaced apart first device semiconductor channel material nanosheets from the plurality of vertically stacked and spaced apart second device semiconductor channel material nanosheets.

4. The semiconductor device of claim 3, wherein the gate structure wraps around a middle portion of the middle dielectric isolation layer.

5. The semiconductor device of claim 1, further comprising a blocking spacer contacting an outer sidewall of both the first device semiconductor material structure and the second device semiconductor material structure.

6. The semiconductor device of claim 1, further comprising a first device source/drain region extending outward from each first device semiconductor channel material nanosheet and a second device source/drain region extending outward from each second device semiconductor channel material nanosheet, wherein the first device source/drain region and the second device source/drain region are separated by a source/drain separating dielectric layer.

7. The semiconductor device of claim 6, further comprising a first device dielectric liner located on a sidewall and a bottommost surface of the source/drain separating dielectric layer.

8. The semiconductor device of claim 1, further comprising a first device inner spacer located above and beneath each end portion of each first device semiconductor channel material nanosheets and the first device semiconductor material structure and a second device inner spacer located beneath each end portion of each second device semiconductor channel material nanosheets and the second device semiconductor material structure.

9. The semiconductor device of claim 1, wherein the first nanosheet transistor is of a first conductivity type, and the second nanosheet transistor is of a second conductivity type, wherein the first conductivity type is different from the second conductivity type.

10. A semiconductor device comprising:
a first nanosheet transistor comprising a plurality of vertically stacked and spaced apart first device semiconductor channel material nanosheets, each first device semiconductor channel material nanosheet having a middle portion located in an active gate region and end portions located under a gate spacer, wherein the middle portion of each first device semiconductor channel material nanosheet is thinner than the end portions of each first device semiconductor channel material nanosheet, a gate structure wrapping around the middle portion of each of the first device semiconductor channel material nanosheets, and a first device semiconductor material structure vertically aligned above each end portion of the first device semiconductor channel material nanosheets and having an inner sidewall in contact with the gate structure;
a second nanosheet transistor stacked vertically above the first nanosheet transistor and comprising a plurality of vertically stacked and spaced apart second device semiconductor channel material nanosheets, each second device semiconductor channel material nanosheet having a middle portion located in the active gate region and end portions located under the gate spacer, wherein the middle portion of each second device semiconductor channel material nanosheet is thinner than the end portions of each second device semiconductor channel material nanosheet, the gate structure wrapping around the middle portion of each of the second device semiconductor channel material nanosheets, and a second device semiconductor material structure vertically aligned beneath each end portion of the second device semiconductor channel material nanosheets and having an inner sidewall in contact with the gate structure; and
a source/drain canyon located on each side of the first nanosheet transistor and the second nanosheet transistor, wherein each source/drain canyon comprises a first device source/drain region and a second device source/drain region, wherein the first device source/drain region and the second device source/drain region are separated by a source/drain separating dielectric layer.

11. The semiconductor device of claim 10, further comprising a bottom dielectric isolation layer located beneath the first nanosheet transistor.

12. The semiconductor device of claim 10, further comprising a middle dielectric isolation layer separating the plurality of vertically stacked and spaced apart first device semiconductor channel material nanosheets from the plurality of vertically stacked and spaced apart second device semiconductor channel material nanosheets.

13. The semiconductor device of claim 12, wherein the gate structure wraps around a middle portion of the middle dielectric isolation layer.

14. The semiconductor device of claim 10, further comprising a blocking spacer contacting an outer sidewall of both the first device semiconductor material structure and the second device semiconductor material structure.

15. The semiconductor device of claim 10, further comprising a first device inner spacer located above and beneath each end portion of each first device semiconductor channel material nanosheet and the first device semiconductor material structure and a second device inner spacer located beneath each end portion of each second device semiconductor channel material nanosheet and the second device semiconductor material structure.

16. The semiconductor device of claim 10, wherein each of the first device source/drain region, the source/drain separating dielectric layer, and the second device source/drain region has a same vertical height in each source/drain canyon.

17. The semiconductor device of claim 10, wherein each of the first device source/drain region and the source/drain separating dielectric layer has a different vertical height in each source/drain canyon.

18. The semiconductor device of claim 10, wherein each of the source/drain separating dielectric layer and the second device source/drain region has a different vertical height in each source/drain canyon.

19. The semiconductor device of claim 10, wherein each of the first device source/drain region, the source/drain separating dielectric layer, and the second device source/drain region has a different vertical height in each source/drain canyon.

20. The semiconductor device of claim 10, wherein the first nanosheet transistor is of a first conductivity type, and the second nanosheet transistor is of a second conductivity type, wherein the first conductivity type is different from the second conductivity type.
